(19) United States
(12) Patent Application Publication
(10) Pub. No.: US 2012/0318353 A1
(43) Pub. Date: Dec. 20, 2012

(54) PHOTOVOLTAIC DEVICE HAVING AN INTEGRATED MICRO-MIRROR AND METHOD OF FORMATION

(75) Inventor: Sridhar Kasichainula, Fremont, CA (US)

(73) Assignee: Sridhar Kasichainula, Fremont, CA (US)

(21) Appl. No.: 13/163,771

(22) Filed: Jun. 20, 2011

(51) Int. Cl. H01L 31/0232

(52) U.S. Cl. 136/259; 438/72; 257/E31.127

(57) ABSTRACT

Disclosed are a system, a method and/or an apparatus of a photovoltaic device having an integrated micro-mirror and of formation. In one embodiment, a photovoltaic structure includes a photovoltaic cell, an oxide layer formed above the photovoltaic cell, and an integrated micro-mirror formed above the oxide layer. The integrated micro-mirror may be fabricated as a flat plate reflection form in which the light energy is deflected to the underlying photovoltaic cell. Alternatively, the integrated micro-mirror may be fabricated in a concentrator form facing a solar source to concentrate a light energy of the solar source into a target region of the integrated photovoltaic cell. An array of the integrated micro-mirrors may be physically bonded to the integrated photovoltaic cell. A shape and geometry of the array of the integrated micro-mirrors may be designed to maximize an efficiency of the integrated photovoltaic cell.

### FIELD OF TECHNOLOGY

The various embodiments relate to a method, apparatus, and/or system of alternative energy, and more specifically to a solar concentrator system employing micro-mirrors.

### BACKGROUND

Photovoltaic technology may involve the use of a solar collector. The solar collector may operate by focusing wide area sunlight into a single point or line using mirrors or combination of optics. A receiver or multiple receivers (e.g., a photovoltaic receiver, a solar thermal receiver) may receive the concentrated sunlight to generate electrical energy and/or to perform work. A reflector and/or a lens of the solar collector may be produced separately. Proper alignment and tracking of sunlight may be required for efficient operation of solar energy system. At higher concentration ratios absorbed energy also may increase. Heat generated may need to be driven out with forced air and/or water making it costly and complicated. As such, the use of the solar concentrator can be very inefficient and expensive in a variety of solar technology deployments.

### SUMMARY

A system, a method and/or an apparatus of a photovoltaic device having an integrated micro-mirror and of formation are disclosed. In one aspect, a photovoltaic structure includes a photovoltaic cell, an oxide layer formed above the photovoltaic cell, and an integrated micro-mirror formed above the oxide layer. The integrated micro-mirror may be fabricated as a flat plate reflection form in which the light energy is deflected to the underlying photovoltaic cell. Alternatively, the integrated micro-mirror may be fabricated in a concentrator form facing a solar source to concentrate a light energy of the solar source into a target region of the integrated photovoltaic cell.

An array of the integrated micro-mirrors may be physically bonded to the integrated photovoltaic cell. A shape and geometry of the array of the integrated micro-mirrors may be designed to maximize an efficiency of the integrated photovoltaic cell. Different arrangements may be made of the array to form a vertical, a conical, a hexagonal, a cylindrical, a parabolic concave, and/or a saw-tooth type structure. The integrated micro-mirror may be etched directly above the photovoltaic cell. The photovoltaic cell may be formed with an n-type doped Silicon material using a CMOS process.

The integrated micro-mirror may be formed of a material including a copper element, an aluminum element, a silver element, a gold element, a chromium element, a nickel element, a palladium element, a platinum element, a zinc element, a bismuth element, an indium element, a rhodium element, a ruthenium element, a titanium element, and/or a vanadium element. The integrated micro-mirror may be a glass, a ceramic and/or a polyethylene material.

A reflective layer above the integrated micro-mirror may be formed. The reflective layer may be formed through a painting process of a reflective metal directly on the integrated micro-mirror using at a thermosetting polymer, an epoxy resin, a polyester material, a polyurethane material, an acrylic material, and a melamine material, and/or an etching process in which silicon is etched directly above silicon to form the reflective layer. The integrated micro-mirror may be formed on a separate semiconductor wafer and bonded to a base photovoltaic cell wafer. A Pyrex glass may be bonded to the integrated micro-mirror to permit the light energy of the solar source to pass through.

The photovoltaic structure may include a set of localized contacts adjacent to a lower surface of the photovoltaic cell to permit transmission of electrical energy to an external source. An efficiency of the photovoltaic cell may be increased by a factor of at least two through the integrated micro-mirror. Multiple ones of the flat plate reflection form, the concentrator form, and the hexagonal form may be used in a set of the integrated micro-mirrors forming the photovoltaic structure.

In another aspect, a method of fabrication of a photovoltaic structure includes forming a photovoltaic cell, forming an oxide layer above the photovoltaic cell, and forming an integrated micro-mirror above the oxide layer. The integrated micro-mirror may be formed in a concentrator form (e.g., a semi-circular form) as shown in FIG. 3 facing a solar source to concentrate a light energy of the solar source into a target region of the photovoltaic cell physically bonded to the integrated micro-mirror. Alternatively, the integrated micro-mirror may be formed in a flat plate reflection form in which the light energy is deflected to the underlying photovoltaic cell.

In yet another aspect, a photovoltaic structure includes a photovoltaic cell, an oxide layer formed above the photovoltaic cell, and an integrated micro-mirror formed above the oxide layer.

The other aspects of the current invention will become apparent from the following description and accompanying drawings. The methods and systems disclosed herein may be implemented in any means known in the art for achieving various aspects of the present invention.

### BRIEF DESCRIPTION OF DRAWINGS

Example embodiments are illustrated by way of example and not limitation in the figures of the accompanying drawings, in which like references indicate similar elements and in which:

FIG. 1A-1G are graphical process flows which illustrate a formation of an integrated micro-mirror formed above an oxide layer of a photovoltaic cell of a photovoltaic structure, according to one embodiment.

FIG. 2 is a flat plate reflection form view of the photovoltaic structure, according to one embodiment.

FIG. 3 is a concentrator form view of the photovoltaic structure, according to one embodiment.

FIG. 4 is a hexagonal form view of the photovoltaic structure, according to one embodiment.

FIG. 5 is a system view of the photovoltaic structure having an array of integrated micro-mirrors which channel a light energy of a solar source to photovoltaic cells of the photovoltaic structure, according to one embodiment.

FIG. 6 is a glass embodiment view of the photovoltaic structure, according to one embodiment.

FIG. 7 is a form embodiment view of the integrated micro-mirror, according to one embodiment.

FIG. 8 is a light channel view of the photovoltaic cell, according to one embodiment.

FIG. 9 is a light channel view in a cube form of the integrated micro-mirror, according to one embodiment.

FIG. 10 is a table view of a fraction of output current verses an angle of incidence in degrees, according to one embodiment.

FIG. 11 is a table view of a fraction of reflection verses an angle of incidence in degrees, according to one embodiment.

FIG. 12 is a table view of a fraction of shadow verses an angle of incidence in degrees, according to one embodiment.

FIG. 13 is a process flow of forming an integrated micro-mirror above the photovoltaic cell in the photovoltaic structure, according to one embodiment.

FIG. 14 is a saw view of the photovoltaic structure, according to one embodiment.

Other features of the present embodiments will be apparent from the accompanying, drawings and from the detailed description that follows.

### DETAILED DESCRIPTION

A system, a method and/or an apparatus of a photovoltaic device having an integrated micro-mirror and of formation are disclosed. In the following description of preferred embodiments, reference is made to the accompanying drawings which form a part hereof, and in which it is shown by way of illustration specific embodiments in which the invention can be practiced. It is to be understood that other embodiments can be utilized and structural changes can be made without departing from the scope of the preferred embodiments.

In one embodiment, a photovoltaic structure 550 includes a photovoltaic cell, an oxide layer formed above the photovoltaic cell 100, and an integrated micro-mirror 104 formed above the oxide layer. The integrated micro-mirror 104 may be fabricated as a flat plate reflection form in which the light energy is deflected to the underlying photovoltaic cell 100. Alternatively, the integrated micro-mirror 104 may be fabricated in a concentrator form facing a solar source to concentrate a light energy 202 of the solar source 200 into a target region 310 of the integrated photovoltaic cell 100.

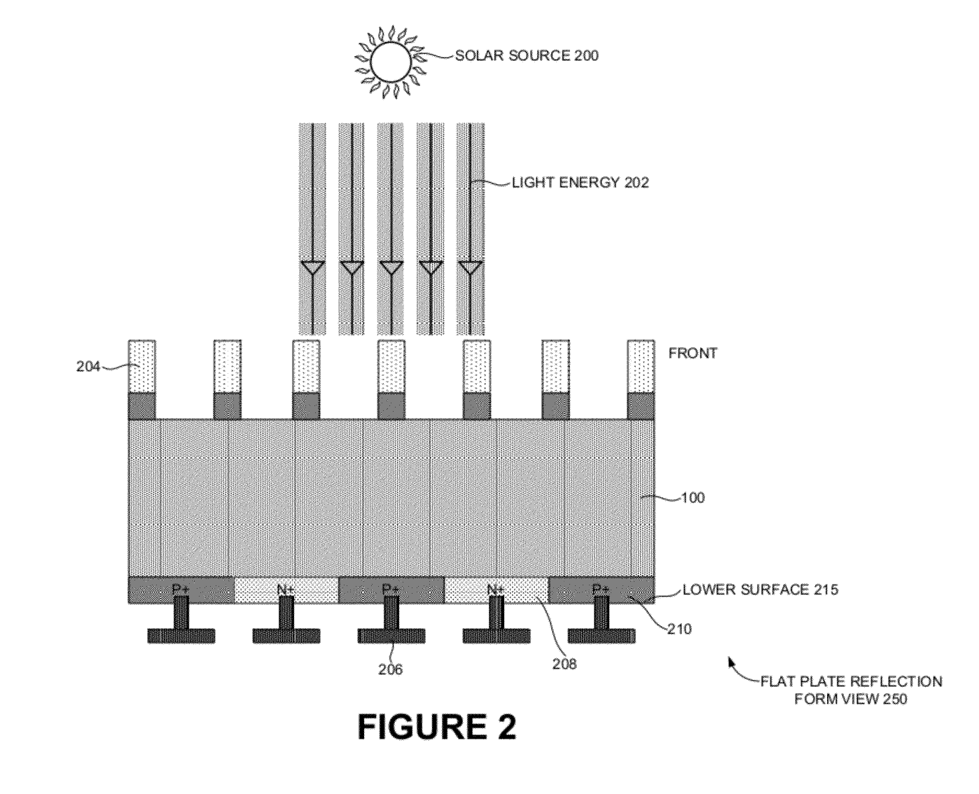

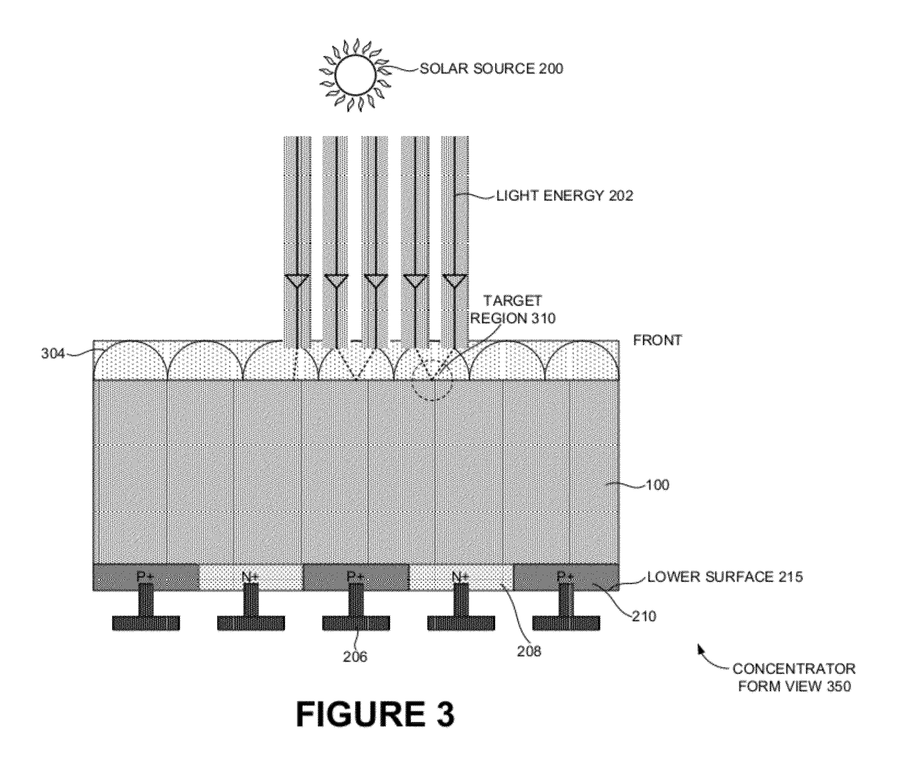

In another embodiment, a method of fabrication of a photovoltaic structure 550 includes forming a photovoltaic cell 100, forming an oxide layer 102 above the photovoltaic cell 100, and forming an integrated micro-mirror 104 above the oxide layer 102. The integrated micro-mirror 104 may be formed in a concentrator form (e.g., a semi-circular form) as shown in FIG. 3 facing a solar source 200 to concentrate a light energy 202 of the solar source 200 into a target region 310 of the photovoltaic cell 100 physically bonded to the integrated micro-mirror 104. Alternatively, the integrated micro-mirror 104 may be formed in a flat plate reflection form (see FIG. 2) in which the light energy 202 is deflected to the underlying photovoltaic cell 100.

In yet another embodiment, a photovoltaic structure 550 includes a photovoltaic cell 100, an oxide layer 102 formed above the photovoltaic cell 100, and an integrated micro-mirror 104 formed above the oxide layer 102.

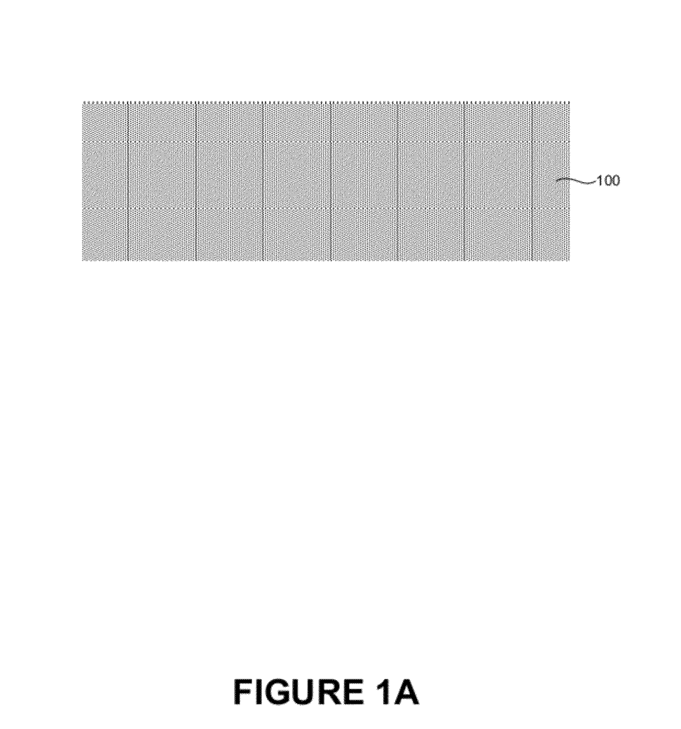

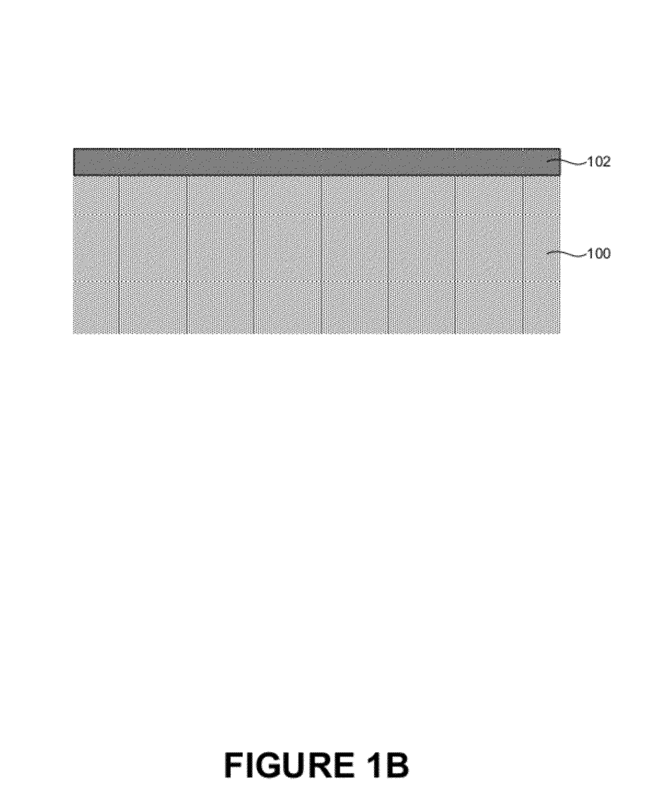

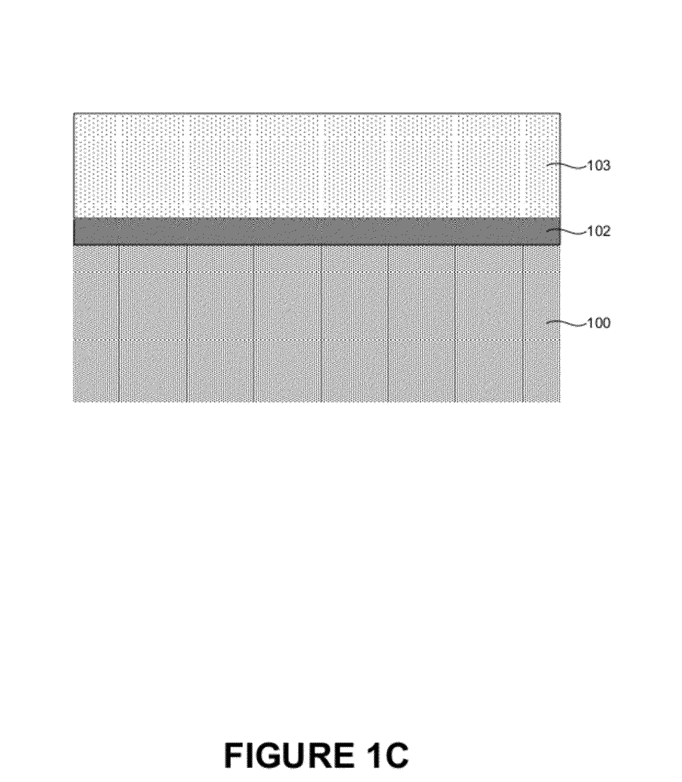

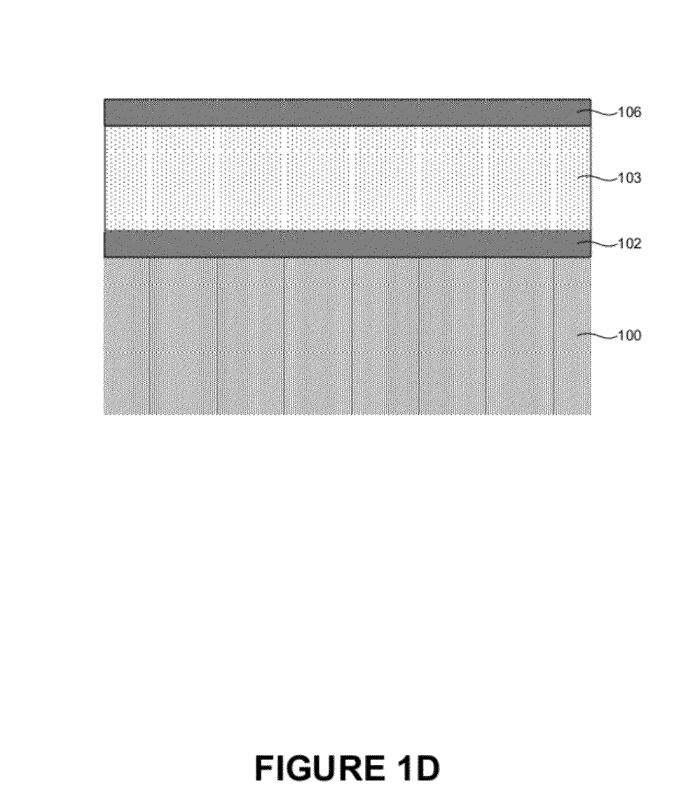

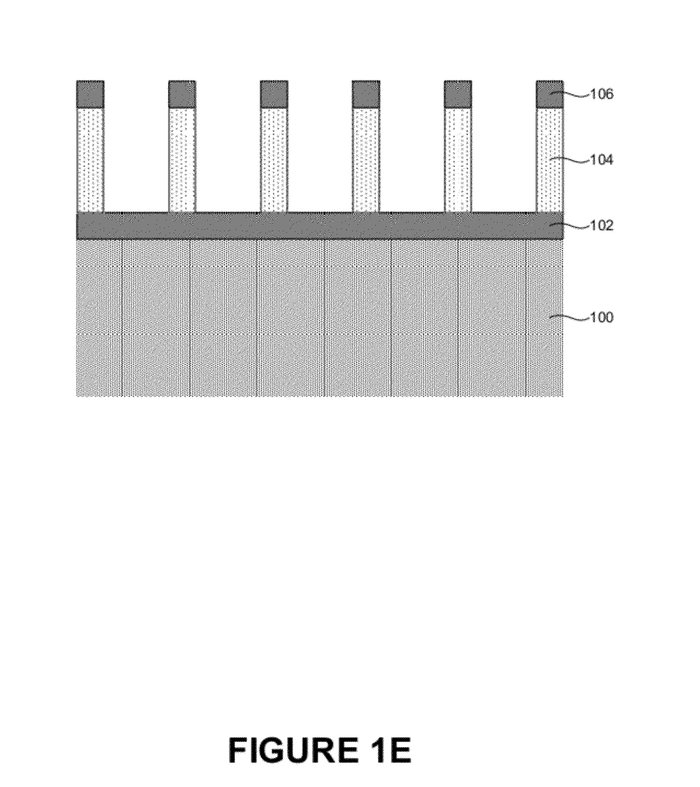

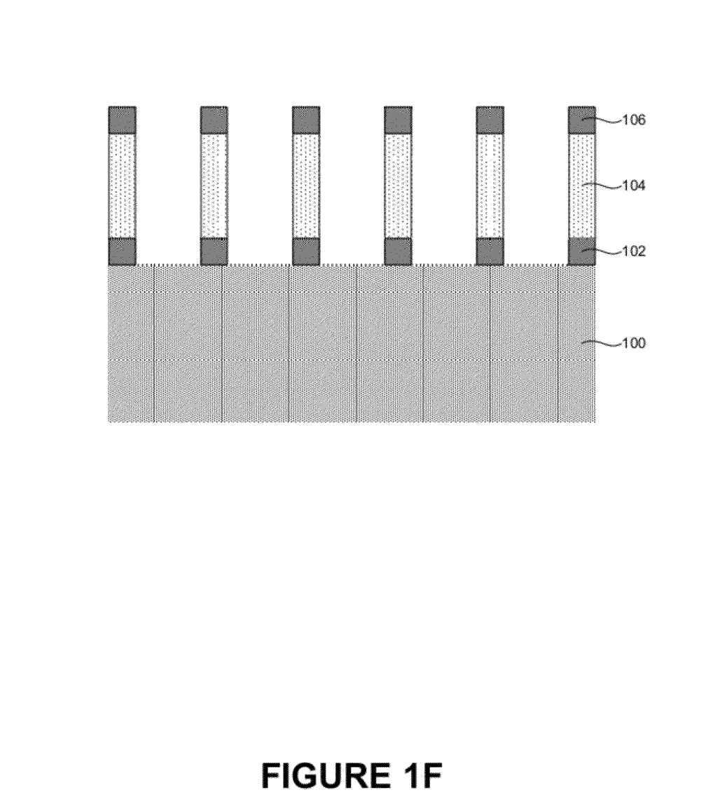

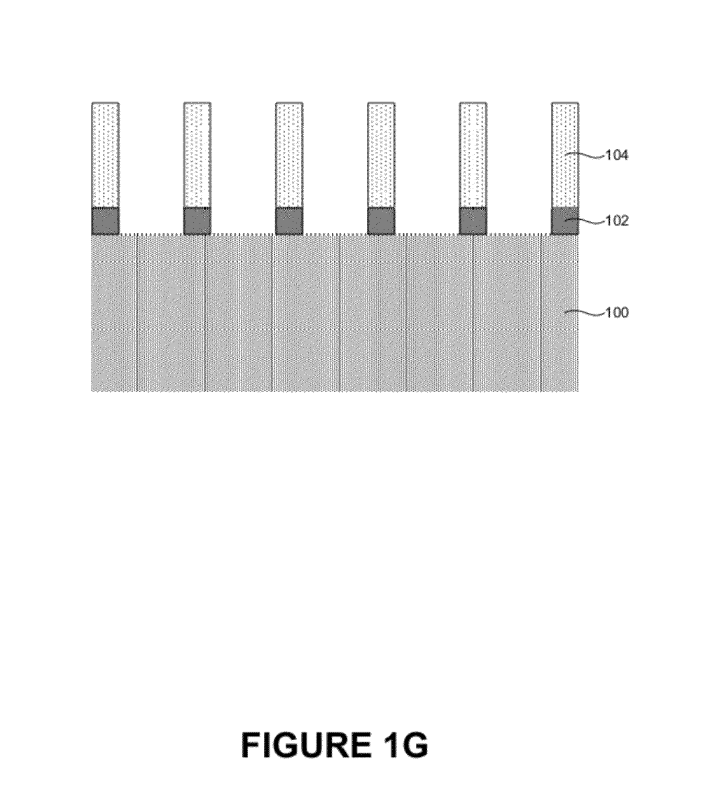

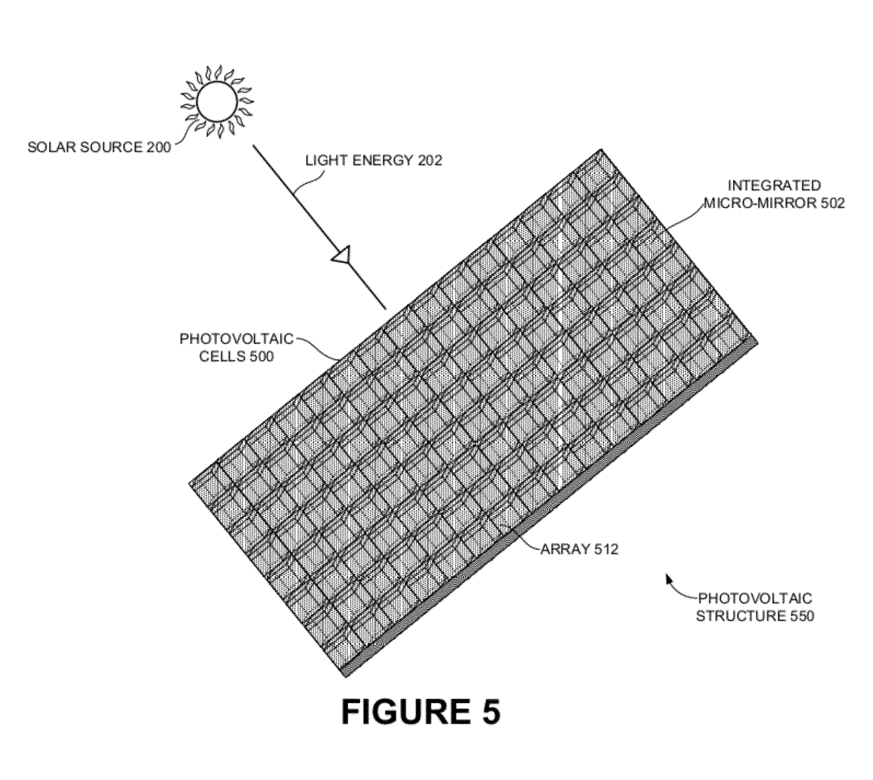

FIG. 1A-1G are graphical process flows which illustrate a formation of an integrated micro-mirror 104 formed above an oxide layer 102 of a photovoltaic cell 100 of a photovoltaic structure 550 (as shown in FIG. 5), according to one embodiment.

FIG. 1A illustrates the photovoltaic cell 100 by itself. Then, in FIG. 1B, the oxide layer 102 is illustrated as being formed above the photovoltaic cell 100. Next, in FIG. 1C, a metal 103 (e.g., aluminum) is deposited above the oxide layer 102. Then, in FIG. 1D, a photo-resist material 106 is added above the metal 103. Next, in FIG. 1E, the metal is etched to pattern into an integrated micro-mirror 104. The integrated micro-mirror 104 may be formed of a material including a copper element, an aluminum element, a silver element, a gold element, a chromium element, a nickel element, a palladium element, a platinum element, a zinc element, a bismuth element, an indium element, a rhodium element, a ruthenium element, a titanium element, and/or a vanadium element. The integrated micro-mirror 104 may be a glass, a ceramic and/or a polyethylene material.

Then, in FIG. 1F, the oxide layer 102 is removed underneath the portions in which the metal 103 was removed to form the integrated micro-mirror 104. Finally, in FIG. 1G, the photo-resist 106 is removed to expose the integrated micro-mirror 104.

FIG. 2 is a vertical reflection form view 250 of the photovoltaic structure 550, according to one embodiment. Particularly, FIG. 2 shows a solar source 200, a light energy 202 emanating from the solar source 200. The light energy 202 is channeled and/or reflected by the flat plate integrated micro-mirrors 204, which reflect on to the photovoltaic cell 100. In an alternate embodiment, a lightly doped layer (not shown) may be formed above the photovoltaic cell 100 on which the light energy 202 is channeled.

The flat plate integrated micro-mirror 204 may be fabricated as a flat plate reflection form (e.g., as shown in the flat plate reflection form view 250 of FIG. 2 in which the integrated micro-mirrors 204 are flat and rectangular in structure) in which the light energy 202 is deflected to the underlying photovoltaic cell 100. The photovoltaic cell 100 may include a set of localized contacts 206 adjacent to a lower surface 215 of the photovoltaic cell 100 of the photovoltaic structure 550 to permit transmission of electrical energy to an external source through P type 206 and n-type 208 contacts, as shown in FIG. 2.

FIG. 3 is a concentrator form view 350 of the photovoltaic structure 550, according to one embodiment. The concentrator form integrated micro-mirror 304 may be fabricated in a concentrator form of FIG. 3 (in which the concentrator form integrated micro-mirrors 304 are semi-spherical in structure) facing a solar source 200 to concentrate a light energy 202 of the solar source 200 into a target region 310 of the integrated photovoltaic cell 100.

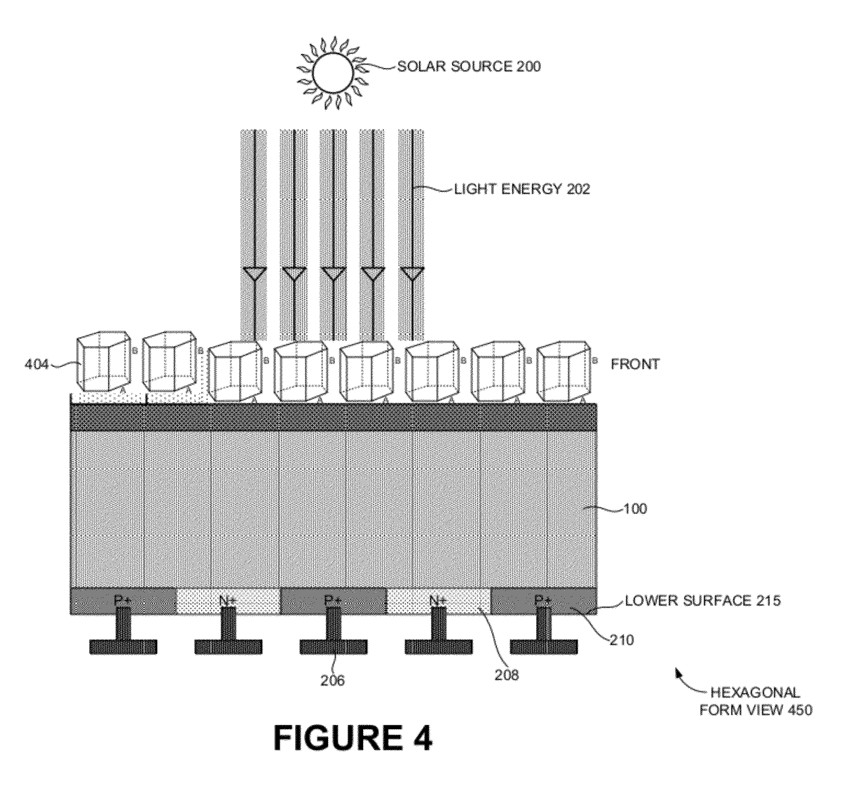

FIG. 4 is a hexagonal form view 450 of the photovoltaic structure 550, according to one embodiment. The hexagonal form integrated micro-mirror 404 may be fabricated in a hexagonal form of FIG. 4 (in which the hexagonal integrated micro-mirrors 404 are semi-spherical in structure) facing a solar source 200 to concentrate a light energy 202 of the solar source 200 into a target region 310 of the integrated photovoltaic cell 100.

FIG. 5 is a system view of the photovoltaic structure 550 having an array of integrated micro-mirror 104s which channel a light energy 202 of a solar source 200 to photovoltaic cell 100s of the photovoltaic structure 550, according to one embodiment. In one aspect, a photovoltaic structure 550 includes a photovoltaic cell 100, an oxide layer 102 formed above the photovoltaic cell 100, and an integrated micro-mirror 104 formed above the oxide layer 102.

An array 512 of the integrated micro-mirrors 502 as illustrated as in FIG. 5 may be physically bonded to the integrated photovoltaic cells 500 underneath each of the integrated micro-mirrors 502. A shape and geometry of the array 512 of the integrated micro-mirrors 502 may be designed to maximize an efficiency of the integrated photovoltaic cell 100. The integrated micro-mirrors 504 may be etched directly above the photovoltaic cells 500. The photovoltaic cells 500 may be formed with an n-type doped Silicon material using a CMOS process. Multiple ones of the flat plate reflection form (e.g., a vertical reflection form) as shown in FIG. 2, the concentrator form (e.g., a semi-spherical form) as shown in FIG. 3, and the hexagonal form 404 as shown in FIG. 4 may be used in a set of the integrated micro-mirrors 504 forming the photovoltaic structure 550.

An efficiency of the photovoltaic cell 100 may be increased by a factor of at least two through the integrated micro-mirror 104. In another aspect, a method of fabrication of a photovoltaic structure 550 includes forming a photovoltaic cell 100, forming an oxide layer 102 above the photo voltaic cell, and forming an integrated micro-mirror 104 above the oxide layer 102. Alternatively, the integrated micro-mirror 104 may be formed in a flat plate reflection form 250 in which the light energy 202 is deflected to the underlying photovoltaic cell 100.

In yet another aspect, a photovoltaic structure 550 includes a photovoltaic cell 100, an oxide layer 102 formed above the photo voltaic cell, and an integrated micro-mirror 104 formed above the oxide layer 102.

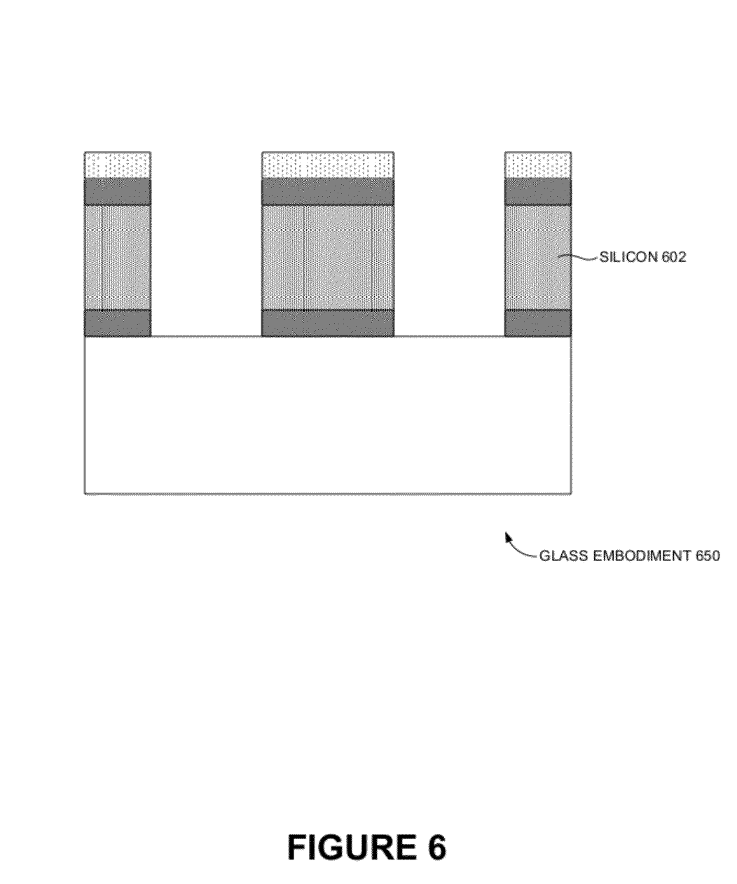

FIG. 6 is a glass embodiment view of the photovoltaic structure 550, according to one embodiment the top reflective layer may be formed using thermosetting polymer, an epoxy resin, a polyester material, a polyurethane material, an acrylic material, and a melamine material on top of the mirror to enhance the reflection.

In another embodiment silicon is etched directly above the underlying silicon 602 photovoltaic structure to form the reflective layer. The integrated micro-mirror 104 may be formed on a separate semiconductor wafer and bonded to a base photovoltaic cell 100 wafer, as shown in the glass embodiment 650 of FIG. 6. A Pyrex glass may be bonded to the integrated micro-mirror 104 to permit the light energy 202 of the solar source 200 to pass through, as shown in the glass embodiment 650 of FIG. 6.

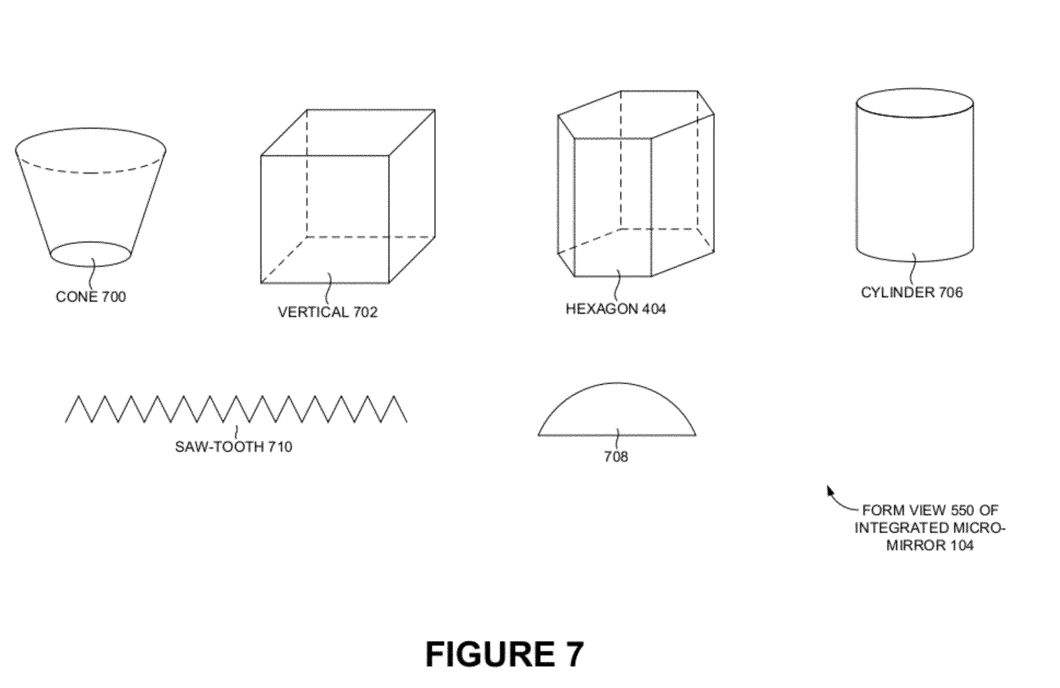

FIG. 7 is a form embodiment view of the integrated micro-mirror 104, according to one embodiment. Different arrangements may be made of the array to form a vertical 702, a conical 700, a hexagonal 404, a cylindrical 706, a parabolic concave 708, and/or a saw-tooth type structure 710.

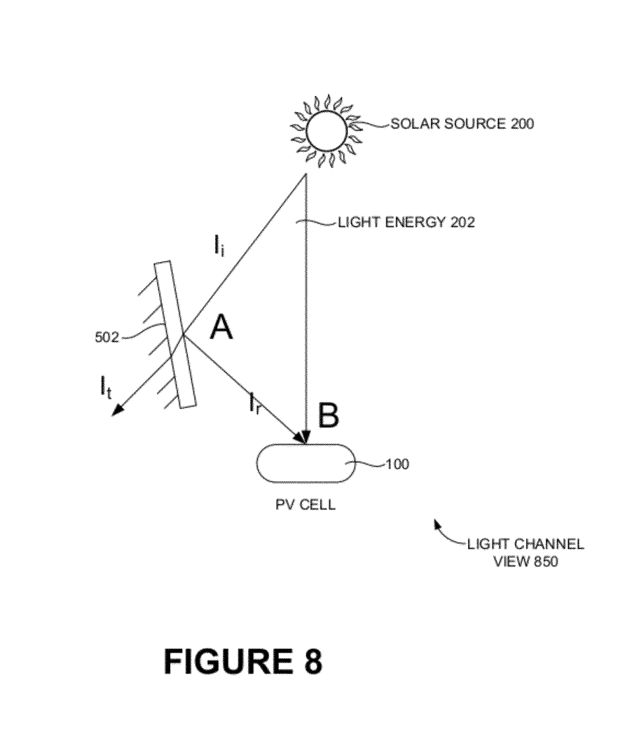

FIG. 8 is a light channel view 850 of the photovoltaic cell 100, according to one embodiment. Particularly, FIG. 8 illustrates the reflection of the light energy 202 from the integrated micro-mirrors 502 on to the photovoltaic cell 100, according to one embodiment.

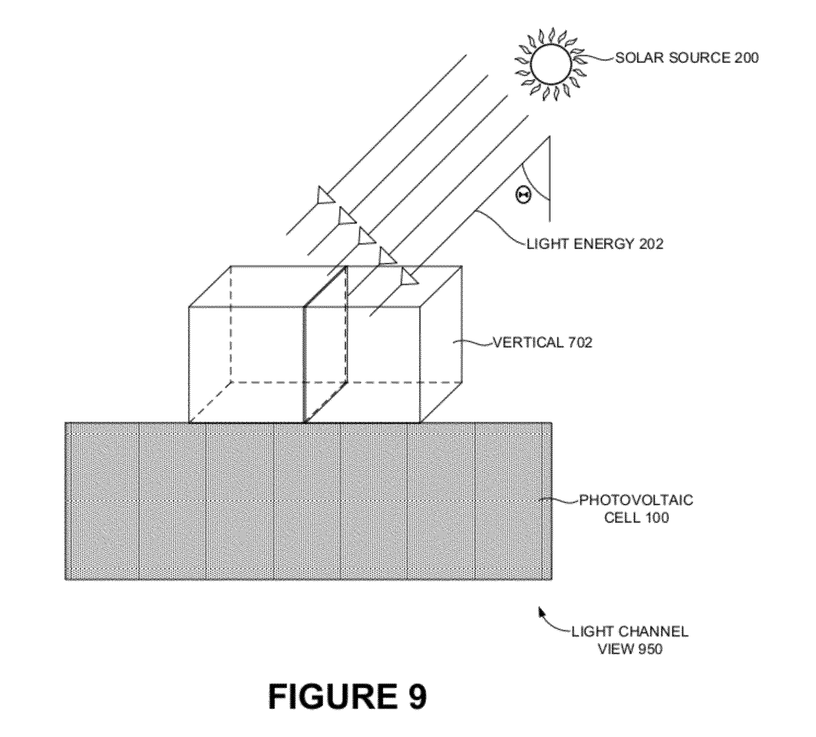

FIG. 9 is a light channel view 950 in a cube form of the integrated micro-mirror 104, according to one embodiment. Particularly, FIG. 9 illustrates the reflection of the light energy 202 from the vertical micro-mirrors 702 on to the photovoltaic cell 100, according to one embodiment.

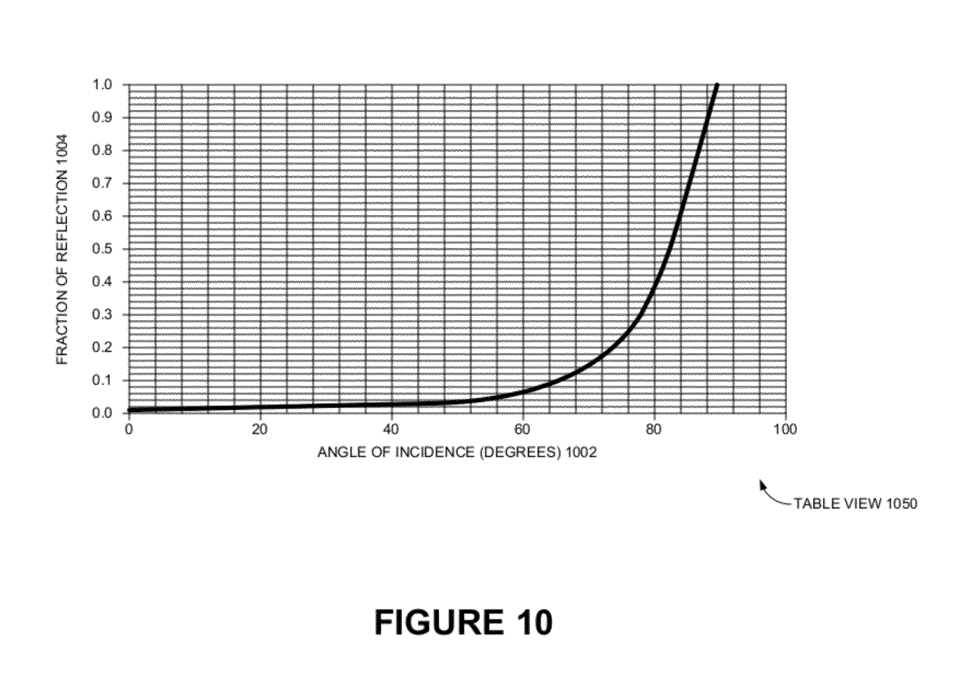

FIG. 10 is a table view 1050 of a fraction of output current verses an angle of incidence in degrees, according to one embodiment. Particularly, FIG. 10 illustrates an exponential rise of the fraction of reflection 1004 as the angle of incidence 1002 in degrees increases.

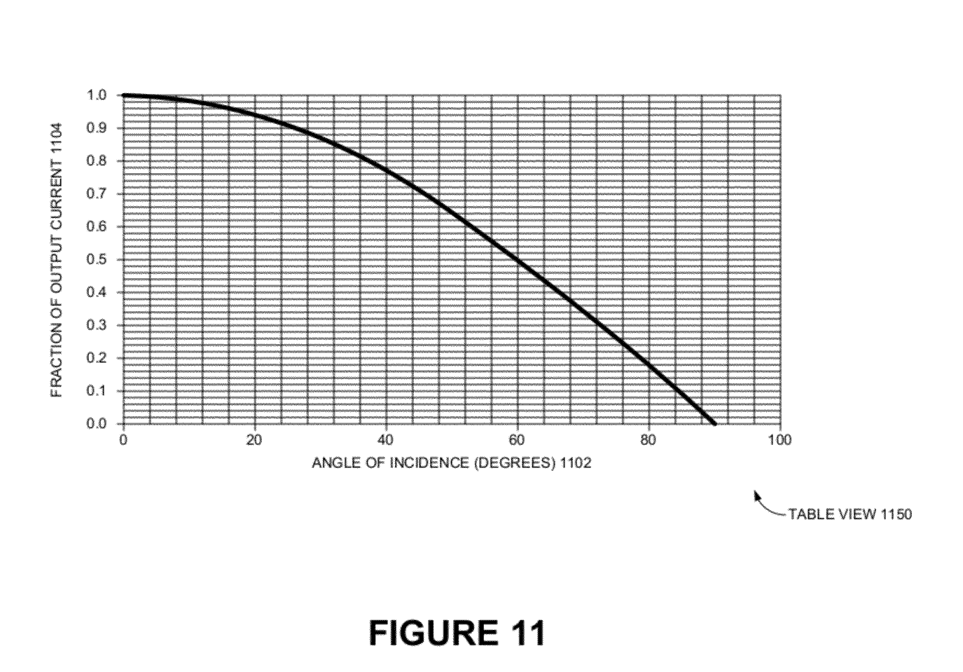

FIG. 11 is a table view 1150 of a fraction of reflection verses an angle of incidence in degrees, according to one embodiment. Particularly, FIG. 11 illustrates an exponential decay of the fraction of output current 1104 as the angle of incidence 1102 in degrees increases.

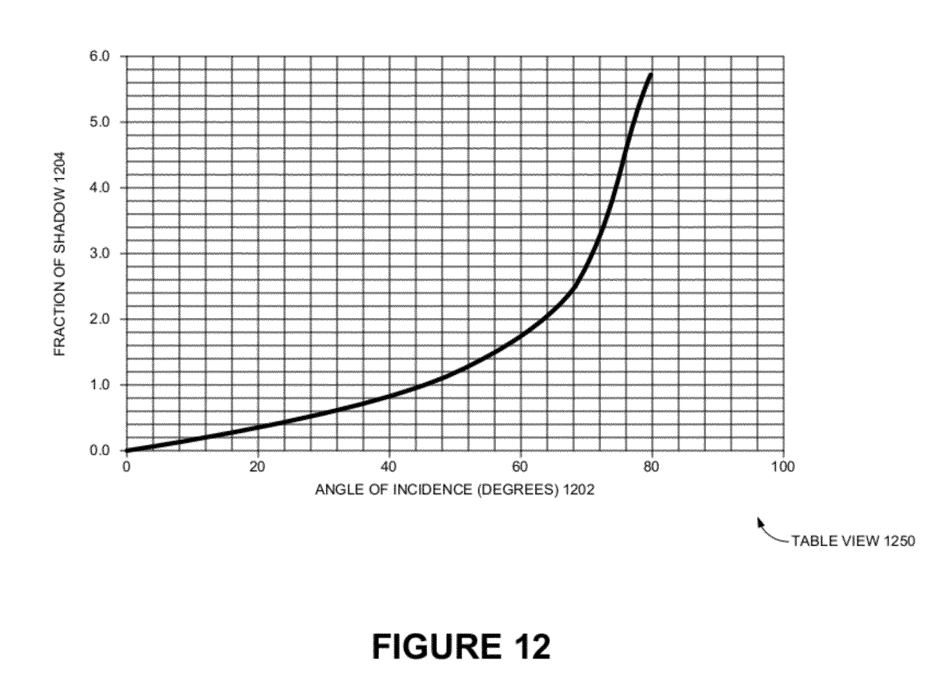

FIG. 12 is a table view 1250 of a fraction of shadow verses an angle of incidence in degrees, according to one embodiment. Particularly, FIG. 12 illustrates an exponential rise of the fraction of shadow 1204 as the angle of incidence 1202 in degrees increases.

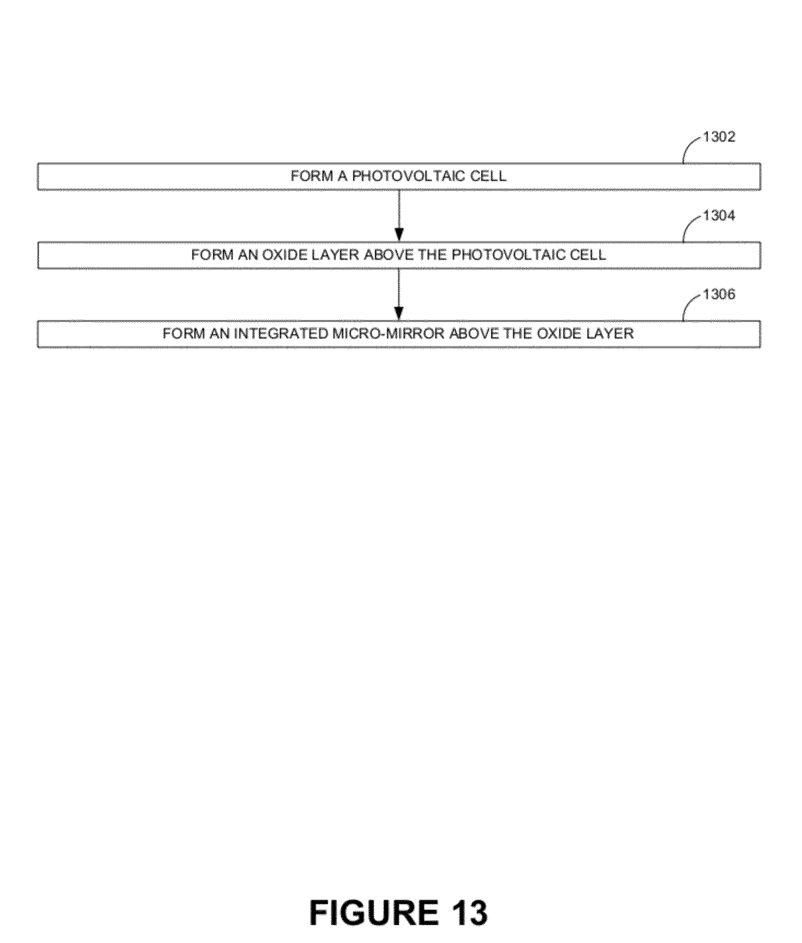

FIG. 13 is a process flow of forming an integrated micro-mirror 104 above the photovoltaic cell 100 in the photovoltaic structure 550, according to one embodiment. Particularly, in operation 1302 a photovoltaic cell 100 is formed. Then, in operation 1304, an oxide layer 102 is formed above the photovoltaic cell 100. Then, in operation 1306, an integrated micro-mirror 104 is formed above the oxide layer 106.

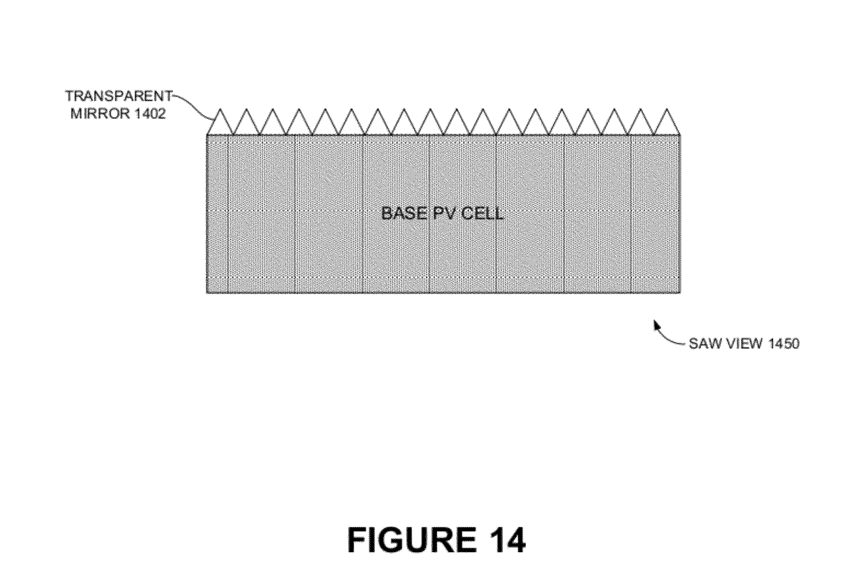

FIG. 14 is a saw view 1450 of the photovoltaic structure 550, according to one embodiment. Particularly, FIG. 14 illustrates the saw-tooth type structure 710 as a method of forming the saw type integrated micro-mirrors in order to concentrate the light energy 202 from the solar source 200.

Various embodiments as described in the descriptions of the FIGS. 1-14 will now be discussed in greater detail. High performance photovoltaic systems (e.g., such as the photovoltaic structure 550) may be important for both economic and technical reasons. The photovoltaic structure 550 may deliver significant performance improvements in performance, cost, and efficiency. Until the development of the formation process described herein of the photovoltaic structure 550, vast physical area may be required to provide the needed power using solar cells. The photovoltaic structure 550 as described in FIGS. 1-14 may help to make solar ubiquitous and cost competitive to traditional energy solutions solar cell efficiency.

In some embodiments, concentrator photovoltaics (CPV) may be improved in the embodiments illustrated in FIGS. 1-14. By trading expensive PV semiconductor materials for cheaper plastic lenses and/or metal mirrors, CPV systems can, in principle, improve performance and reduce overall PV module costs as described in the various embodiments. Parabolic reflectors or lenses that focus the light beam (as shown in FIG. 2) may create a more intense beam of solar energy that is directed onto a small photovoltaic cell (e.g., the photovoltaic cell 100). As the solar intensity is increased from the solar source 200, the generated current (e.g., light energy 202) in the solar source 202 may increase proportionally. The various embodiments described herein may solve a fundamental problem in that the photovoltaic structure 550 is inexpensive to produce, operate and maintain.

Particularly, number of advantages may be present in using the concentrator systems described in FIGS. 1-14. The reflectors and/or lenses used in the various embodiments described in FIGS. 1-14 are produced in an integrated form, and therefore painstaking assembly is avoided. This minimizes cost to provide the proper alignment between the focused beam and the photovoltaic cell. Furthermore, a separate tracking mechanism is not required in the various embodiments of FIGS. 1-14 to track the position of the sun and reflect solar energy towards the integrated micro-mirrors 502 (of FIG. 5). As such, a shading effect is minimized (particularly through the hexagonal integrated micro mirror 404), which in turn increase the peak power output.

At higher concentration ratios (>5) absorbed energy may also increase and heat generated does need to be driven out with forced air or water in the various embodiments of FIGS. 1-14. (e.g, which is costly and complicated). The various embodiments describing a concentrating solar collector of FIGS. 1-14 minimize the shading issue, and its associate expensive assembly and maintenance costs associated with conventional concentrating solar collectors. The various embodiments of FIGS. 1-14 operate at low concentration ratio (<5) in which there is no need of excess heat removal from the PV cell. By careful design of solar cell utilizing inexpensive concentrating systems, it is possible to significantly increase the efficiency and thus achieving an economical advantage over traditional solutions.

Example embodiments include a solar cell structure (e.g., the photovoltaic structure 550) having higher efficiency compared to conventional solar cell. Example embodiments in FIGS. 1-14 also include a method of fabricating the same using conventional CMOS process operations on a silicon. The new solar cell structure in FIGS. 1-14 may include either a concentrating transparent mirror(s) or reflecting mirror(s) in the front side of the existing PV structure to enhance the light intensity and thus improve the efficiency of the cell.

In one embodiment, a mirror or other reflecting surface may be used for collecting and reflecting incident solar radiation in FIGS. 1-14. In one example, the mirror may be directly etched on top of the base PV cell in metal layer similar to conventional CMOS processes in FIGS. 1-14. The reflective layer may be a layer of aluminum, a standard metal used in regular CMOS process in FIGS. 1-14. The reflective layer could be of any metal (one or more of copper, aluminum, silver, gold, chromium, nickel, palladium, platinum, zinc, bismuth, indium, rhodium, ruthenium, titanium and vanadium) or glass or ceramic or plastic in FIGS. 1-14. The mirror also could be silicon directly etched on silicon to form thin reflecting surface in FIGS. 1-14. The reflective layer may be a paint layer, provided as the outermost layer of the mirror in FIGS. 1-14. A number of suitable paints may be used e.g. a thermosetting polymer such as epoxy resin, polyester, polyurethane, acrylic and melamine in FIGS. 1-14.

In another embodiment, the mirror may be formed on a separate wafer and then transferred to the base wafer including a transparent window of Pyrex glass for packaging and letting sunlight go through. A process might include: a). Silicon Nitride deposited Silicon. b) Photoresist to define the etch area c) Etch Silicon Nitride d) Remove photo resist and anodic bonding on the front side e) sputtering of aluminum on the back side of silicon f). Lithography to define etch channels and etch for aluminum and silicon nitride g). Free standing features falls off on Pyrex h). vertical mirrors of silicon with Pyrex frame left after removal of bulk silicon.

In a separate embodiment the mirror may be transparent and may strictly act as a concentrator in FIGS. 1-14. The concentration ratio may depend upon the half-acceptance angle (±θa) and refractive index (n) of the concentrator material that encapsulates the PV cell.

$${C}_{max} = \frac{{n}^{2}}{{sin}^{2} {θ}_{a}}$$

In another separate embodiment, in FIGS. 1-14, the transparent mirrors (e.g. transparent mirror 1402) may be arranged in a saw tooth type fashion where the incident light is concentrated in a particular spot with total internal reflection. It should be understood that someone in this art can come up with different shape, size and geometry and or arrangement to maximize the efficiency of the solar cell.

Various shapes and geometries may be possible in FIGS. 1-14. One can simply think of various shapes and geometries to maximize the incident light intensity and minimize the shadow in FIGS. 1-14. Below are some of the possible shapes shown as an example but not limiting the scope of the various embodiments. At the base of each shape lies the photovoltaic cell 100 (as shown in FIG. 1A).

Part of the incident light is transmitted and rest is reflected:

Ii=It+Ir

Assume there is negligible transmittance that micro mirror can reflect most of the incident light. Where Reflectance is function of indices. Refractive index for air is 1 and 1.39 for aluminum. Using Fresnel equation we can obtain reflection at a particular angle of incidence.

$$R = {[ \frac{{n}_{1} cos {θ}_{i} - {n}_{2} \sqrt{1 - {( \frac{{n}_{1}}{{n}_{2}} sin {θ}_{i} )}^{2}}}{{n}_{1} cos {θ}_{i} + {n}_{2} \sqrt{1 - {( \frac{{n}_{1}}{{n}_{2}} sin {θ}_{i} )}^{2}}} ]}^{2}$$

PV cell output with respect to sun's (solar source 200) angle of incidence is approximated by a cosine function. Beyond the incident angle of 50 degree available solar energy falls of rapidly.

I=Iₘₐₓ*cos ∝

Use of the integrated micro-mirrors 104 of FIGS. 1-14 can increase the available angle from 50 degree to 90 degree

The efficiency increase will be:

∫₀⁹⁰I cos ∝−∫₀⁵⁰I cos ∝=23.3%

Shadow is 100% at an angle of 45 degree and becomes much larger at large angles of incident light. Height of the mirrors and angle may need to be adjusted for maximum efficiency. Total Efficiency Gain can be calculated using total intensity of the incident beam and area of the cell and any loss due to shadow of the mirrors.

Total efficiency Gain=(Increased intensity due to reflection)*(Increased Area because of the use of mirrors)*(Loss of area due to shadow)=1.23*4*0.5=2.46 times original value

At least twice the performance is possible with careful cell design in FIGS. 1-14.

Base photovoltaic cell 100 and integrated micro mirror 104 arrangements can be shown in the various embodiments of FIGS. 1-14. In one example cell construction, the front side has transparent integrated micro-mirrors 502 acting as a concentrator and backside has localized contacts to outside world. In another example a stack of vertical reflecting mirrors are arranged such that incident light intensity is deflected to underlying PV cell.

The embodiments of FIGS. 1-14 may be enabled using the aid of software and/or hardware robotics and/or instruments used in the fabrication of the photovoltaic structure 550.

Although the present embodiments have been described with reference to specific example embodiments, it will be evident that various modifications and changes may be made to these embodiments without departing from the broader spirit and scope of the various embodiments. For example, the base photovoltaic cell can be formed using various technologies available today such as crystalline silicon, thin films and organic/polymer solar cells.

In addition, it will be appreciated that the various operations, processes, and methods disclosed herein may be enabled through software and or hardware such as a solar tracking system to enable tracking of the solar light throughout the day. Accordingly, the specification and drawings are to be regarded in an illustrative rather than a restrictive sense.

What is claimed is:

1. A photovoltaic structure, comprising:
a photovoltaic cell;
an oxide layer formed above the photovoltaic cell; and
an integrated micro-mirror formed above the oxide layer,
wherein the integrated micro-mirror is fabricated in at least one of:
a flat plate reflection form in which the light energy is deflected to the underlying photovoltaic cell, and
a concentrator form facing a solar source to concentrate a light energy of the solar source into a target region of the integrated photovoltaic cell.

2. The photovoltaic structure of claim 1,
wherein an array of the integrated micro-mirrors are physically bonded to the integrated photovoltaic cell, and
wherein a shape and a geometry of the array of the integrated micro-mirrors are designed to maximize an efficiency of the integrated photovoltaic cell in which different arrangements are made to form at least one of a vertical, a conical, a hexagonal, a cylindrical, a parabolic concave, and a saw-tooth type structure.

3. The photovoltaic structure of claim 1:
wherein the integrated micro-mirror is etched directly above the photovoltaic cell.

4. The photovoltaic structure of claim 3:
wherein the photovoltaic cell is formed with a n-type doped Silicon material using a CMOS process.

5. The photovoltaic structure of claim 4:
wherein the integrated micro-mirror is formed of a material comprising at least one of a copper element, an aluminum element, a silver element, a gold element, a chromium element, a nickel element, a palladium element, a platinum element, a zinc element, a bismuth element, an indium element, a rhodium element, a ruthenium element, a titanium element, and a vanadium element.

6. The photovoltaic structure of claim 5:
wherein the integrated micro-mirror is at least one of a glass, a ceramic and a polyethylene material.

7. The photovoltaic structure of claim 1, further comprising:
a reflective layer above the integrated micro-mirror; and
wherein the reflective layer is formed through at least one of a:
a painting process of a reflective metal directly on the integrated micro-mirror using at least one of a thermosetting polymer, an epoxy resin, a polyester material, a polyurethane material, an acrylic material, and a melamine material, and
an etching process in which silicon is etched directly above silicon to form the reflective layer.

8. The photovoltaic structure of claim 1:
wherein the integrated micro-mirror is formed on a separate semiconductor wafer and bonded to a base photovoltaic cell wafer, and
wherein a Pyrex glass is bonded to the integrated micro-mirror to permit the light energy of the solar source to pass through.

9. The photovoltaic structure of claim 8, further comprising:
a set of localized contacts adjacent to a lower surface of the photovoltaic cell to permit transmission of electrical energy to an external source.

10. The photovoltaic structure of claim 9:
wherein an efficiency of the photovoltaic cell is increased by a factor of at least two through the integrated micro-mirror, and
wherein a multiple ones of the flat plate reflection form, the concentrator form, and the hexagonal form are used in a set of the integrated micro-mirrors forming the photovoltaic structure.

11. A method of fabrication of a photovoltaic structure, comprising:
forming a photovoltaic cell;
forming an oxide layer above the photovoltaic cell; and
forming an integrated micro-mirror above the oxide layer;
wherein the integrated micro-mirror is fabricated in at least one of:
a concentrator form facing a solar source to concentrate a light energy of the solar source into a target region of the photovoltaic cell physically bonded to the integrated micro-micro-mirror, and
a flat plate reflection form in which the light energy is deflected to the underlying photovoltaic cell.

12. The method of fabrication of the photovoltaic structure of claim 11:
wherein the integrated micro-mirror is etched directly above the photovoltaic cell, and
wherein the photovoltaic cell is formed with a n-type doped Silicon material using a CMOS process.

13. The method of fabrication of the photovoltaic structure of claim 12:
wherein the integrated micro-mirror is reflective, and
wherein the integrated micro-mirror is transparent such that the light of the solar source directly penetrates through the integrated micro-mirror to the target region of the photovoltaic cell

14. The method of fabrication of the photovoltaic structure of claim 13:
wherein the integrated micro-mirror is formed of a material comprising at least one of a copper element, an aluminum element, a silver element, a gold element, a chromium element, a nickel element, a palladium element, a platinum element, a zinc element, a bismuth element, an indium element, a rhodium element, a ruthenium element, a titanium element, and a vanadium element.

15. The method of fabrication of the photovoltaic structure of claim 14:
wherein the integrated micro-mirror is at least one of a glass, a ceramic and a polyethylene material.

16. The method of fabrication of the photovoltaic structure of claim 15, further comprising:
forming a reflective layer above the integrated micro-mirror; and
wherein the reflective layer is formed through at least one of a:
a painting process of a reflective metal directly on the integrated micro-mirror using at least one of a thermosetting polymer, an epoxy resin, a polyester material, a polyurethane material, an acrylic material, and a melamine material, and
an etching process in which silicon is etched directly above silicon to form the reflective layer.

17. The method of fabrication of the photovoltaic structure of claim 16:
wherein the integrated micro-mirror is formed on a semiconductor wafer and bonded to a photovoltaic cell wafer, and
wherein a Pyrex glass is bonded to the integrated micro-mirror to permit the light energy of the solar source to pass through.

18. The method of fabrication of the photovoltaic structure of claim 17, further comprising:
a set of localized contacts adjacent to a lower surface of the photovoltaic cell to permit transmission of electrical energy to an external source.

19. The method of fabrication of the photovoltaic structure of claim 17
wherein an efficiency of the photovoltaic cell is increased by a factor of at least two through the integrated micro-mirror,
wherein a multiple ones of the flat plate reflection form, the concentrator form, and the hexagonal form are used in a set of the integrated micro-mirrors forming the photovoltaic structure.

20. A photovoltaic structure, comprising:
a photovoltaic cell;
an oxide layer formed above the photovoltaic cell; and
an integrated micro-mirror formed above the oxide layer.
